(19) United States
(12) Patent Application Publication
(10) Pub. No.: US 2012/0091487 A1
(43) Pub. Date: Apr. 19, 2012

(54) LIGHT EMITTING DIODE PACKAGE AND METHOD FOR MANUFACTURING THE SAME

(75) Inventors: SHIUN-WEI CHAN, Hsinchu (TW); CHIH-HSUN KE, Hsinchu (TW)

(73) Assignee: ADVANCED OPTOELECTRONIC TECHNOLOGY, INC., Hsinchu Hsien (TW)

(21) Appl. No.: 13/169,029

(22) Filed: Jun. 27, 2011

(30) Foreign Application Priority Data
Oct. 15, 2010 (CN) 201010510086.4

(51) Int. Cl. H01L 33/58

(52) U.S. Cl. 257/98; 438/27; 257/E33.06

(57) ABSTRACT

A light emitting diode package comprises a substrate and a lens. The substrate comprises two electrodes and a LED chip disposed thereon, wherein the LED chip electrically connects to one of the electrodes via a conductive wire. The connection between the conductive wire and the corresponding electrode is covered by an encapsulation. The lens is located on the substrate and covers the encapsulation. Moreover, the substrate comprises at least two tunnels inside the covering of the lens penetrating the substrate. A collector is located between the substrate and the lens, wherein a transparent layer is formed inside the collector by injecting fluid material through the tunnels or directly injecting fluid material into the collector. A method for manufacturing the light emitting diode package is also provided.

### TECHNICAL FIELD

The disclosure relates generally to light emitting devices, and more particularly to a light emitting diode package and a method for manufacturing the same.

### DESCRIPTION OF THE RELATED ART

In recent years, light emitting diodes (LEDs) have become more and more popular, due to their low power-consumption, energy saving properties, high efficiency, short reactive time, long life and they contain no mercury. Generally, a LED chip may be operated in coordination with at least one kind of phosphor to produce mixed light, for requiring any determined color and illumination as desired. The phosphor is excited by light emitted from the LED chip, and, then, emits conversed light with different wavelength. Powdered phosphor may be admixed with transparent glue, and be constructed into a phosphor layer or a lens via compression molding or transfer molding. However, conductive wires or pads located upon the LED chip may be dislocated due to impulse or pressure from compression molding or transfer molding in the manufacturing process. Moreover, the phosphor may be congealed in such manufacturing process that leads to non-uniformly of the phosphor layer and a decrease in the excited efficiency of the phosphor.

### BRIEF DESCRIPTION OF THE DRAWINGS

FIG. 1 is a flow chart showing a method for manufacturing a light emitting diode package in accordance with a first embodiment of the disclosure.

FIG. 2 is a cross section of a light emitting diode package of the disclosure.

FIG. 3 is a flow chart showing a method for manufacturing the light emitting diode package in accordance with a second embodiment of the disclosure.

FIG. 4 is a schematic view showing step S27 in accordance with FIG. 3 of the disclosure.

### DETAILED DESCRIPTION

Reference will now be made to the drawings to describe the exemplary embodiments in detail.

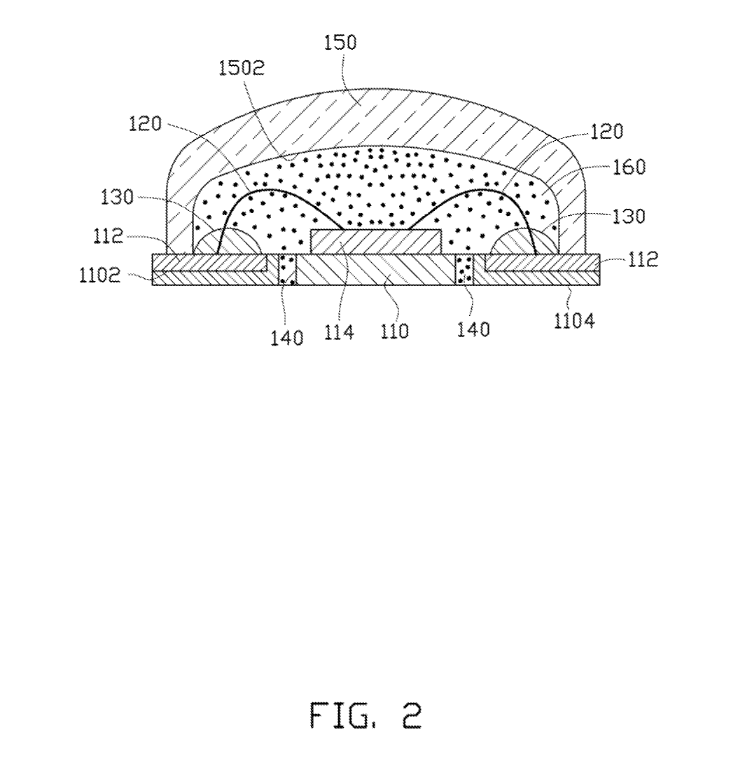

Referring to FIG. 2, the present disclosure provides a light emitting diode package comprising a substrate 110 and a lens 150, wherein the substrate 110 comprises a first surface 1102 and a second surface 1104 opposite each other. Furthermore, the first surface 1102 comprises two electrodes 112, disconnecting each other, respectively extending from the first surface 1102 to the second surface 1104 (not shown in FIG. 2).

A LED chip 114 electrically connects to one of the electrodes 112 via at least one conductive wire 120. In the disclosure, there are two conductive wires 120, respectively electrically connecting the LED chip 114 to the two electrodes 112. In the embodiment, the conductive wires 120 can be composed of gold or other metal that has high electrical conductivity. Moreover, each of the connections between the conductive wire 120 and the corresponding electrode 112 is mantled by an encapsulation 130, whereby the electric conductivity/connections between the electrodes 112 and the conductive wires 120 are protected. In the embodiment, the LED chip 114 has a light emitting angle between about 110° to about 150°. Therefore, light emitted from the LED chip 114 is not obstructed by the two encapsulations 130. In other embodiments, the encapsulations 130 are transparent so that the light emitted from the LED chip 114 would not be obstructed.

The lens 150 is located on the substrate 110 and covers the two encapsulations 130 and the LED chip 114. In the embodiment, the lens 150 is located on the first surface 1102 opposite to the second surface 1104. Moreover, the lens 150 and the encapsulations 130 are adjacent to each other as shown in

FIG. 2. In other embodiments the lens 150 and the encapsulations 130 are separate from each other (not shown). In the disclosure, an adhesive (not shown) is disposed between the lens 150 and the first surface 1102 of the substrate 110, for applying the lens 150 on the substrate 110. A collector 1502 is defined in a recessed bottom surface of the lens 150, wherein the collector 1502 is located between the lens 150 and the substrate 110. The substrate 110 contains at least two tunnels 140 inside the covering of the lens 150 penetrating the substrate 110 from the collector 1502 to the outside. Accordingly, a phosphor layer 160 can be formed inside the collector 1502 via the at least two tunnels 140. In the embodiment, a fluid material is injected inside the collector 1502 via the at least two tunnels 140. After solidification of the fluid material, the phosphor layer 160 is formed inside the collector 1502 and fills the at least two tunnels 140. The phosphor layer 160 comprises phosphor particles therein. In an alternative embodiment, the phosphor layer 160 can be a transparent layer.

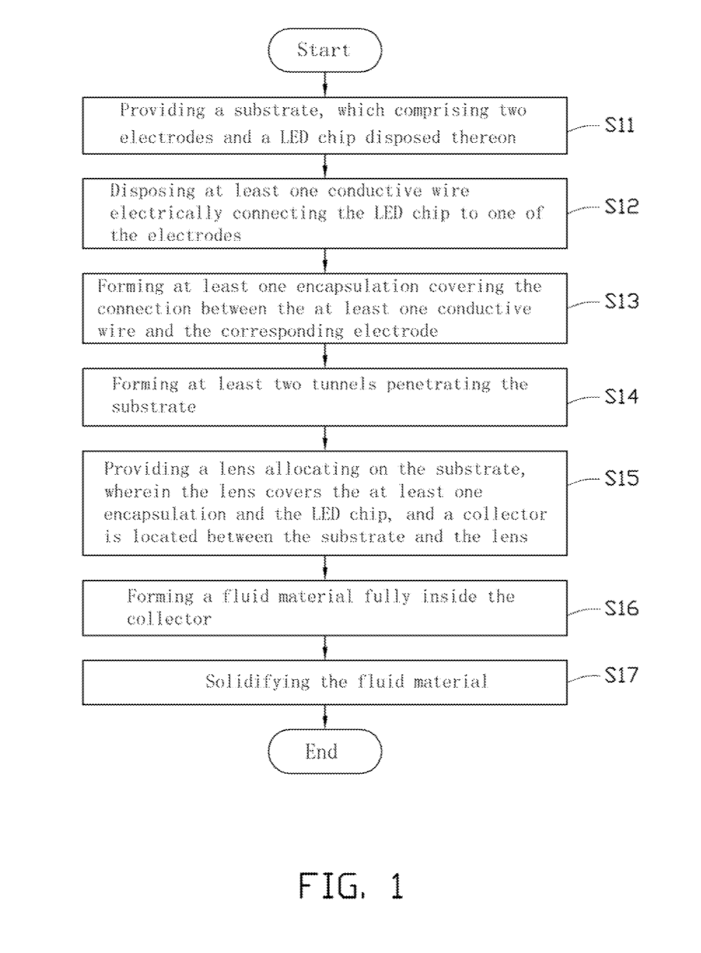

Referring to FIG. 1, the disclosure provides a method for manufacturing a light emitting diode package in accordance with the first embodiment of the disclosure, comprising the following steps:

In step S11, a substrate is provided, wherein two electrodes and a LED chip are disposed thereon.

In step S12, at least one conductive wire is disposed to electrically connect the LED chip to one of the electrodes.

In step S13, at least one encapsulation is formed on the connection between the at least one conductive wire and the corresponding electrode.

In step S14, at least two tunnels are provided on the substrate, wherein the at least two tunnels penetrate through the substrate.

In step S15, a lens is allocated on the substrate, wherein the lens covers the at least one encapsulation and the LED chip, and a collector is located between the substrate and the lens.

In step S16, a fluid material is formed inside the collector. In the disclosure, the fluid material is injected inside the collector via the at least two tunnels.

In step S17, the fluid material is solidified.

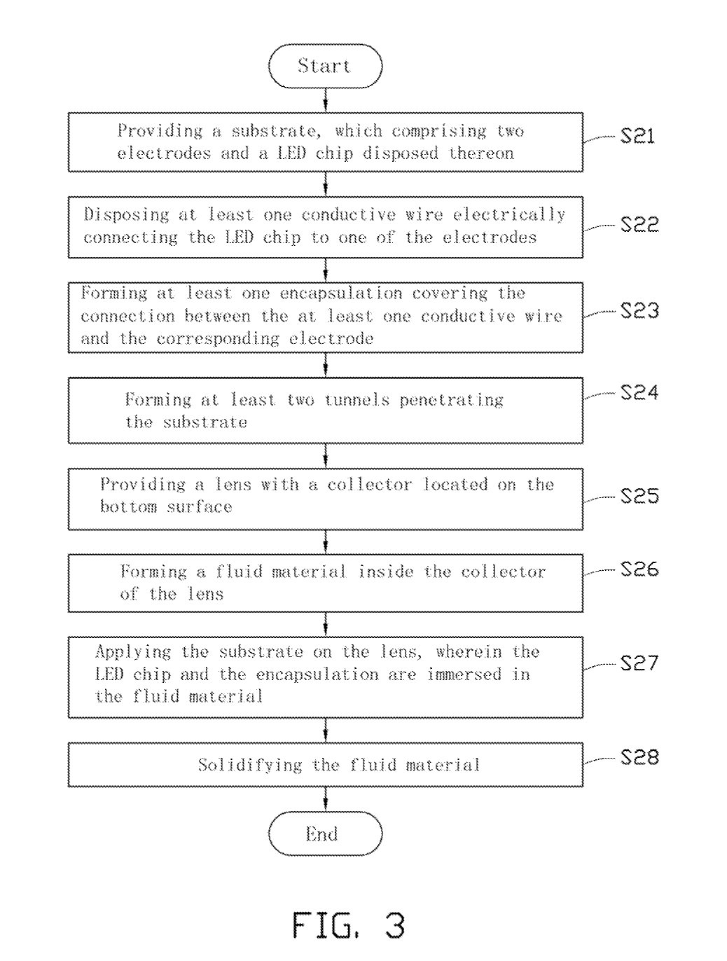

Referring to FIG. 3, the disclosure provides a method for manufacturing a light emitting diode package in accordance with the second embodiment of the disclosure, comprising the following steps:

In step S21, a substrate 210 is provided, wherein two electrodes 212 and a LED chip 214 are disposed thereon.

In step S22, at least one conductive wire 220 is disposed to electrically connect the LED chip 214 to one of the electrodes 212.

In step S23, at least one encapsulation 230 is formed on the connection between the at least one conductive wire 220 and the corresponding electrode 212.

In step S24, at least two tunnels 240 are provided on the substrate 210, wherein the at least two tunnels 240 penetrate through the substrate 210.

In step S25, a lens 250 is provided with a collector 2502 located in a recessed bottom surface thereof

In step S26, a fluid material 260 is formed inside the collector 2502 of the lens 250.

In step S27, the substrate 210 is applied on the lens 250, wherein the LED chip 214 and the at least one encapsulation 230 are immersed in the fluid material 260.

In step S28, the fluid material 260 is solidified to form a phosphor layer.

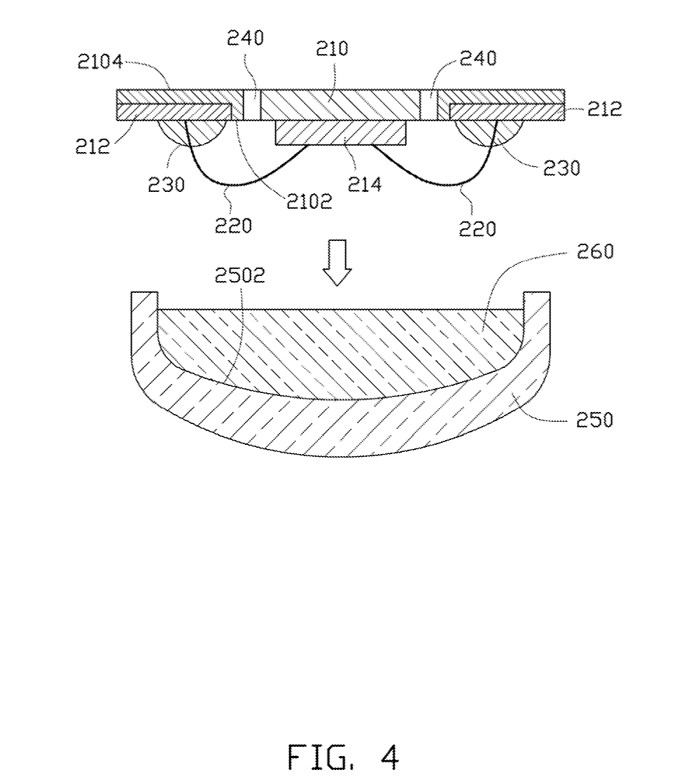

The second embodiment is similar to the first embodiment, only in the difference of before the step of providing the lens 250 allocated on the substrate 210, the fluid material 260 is formed inside the collector 2502 of the lens 250, as shown in FIG. 4. Thereafter, the substrate 210 is applied to the lens 250, at the same time the LED chip 214 and the encapsulations 230 are immersed into the fluid material 260. Finally, the fluid material 260 is solidified and a phosphor layer sandwiched between the lens 250 and the substrate 210 is formed. In an alternative embodiment, the phosphor layer can be a transparent layer.

The disclosure provides the light emitting diode package and the method for manufacturing the same, wherein the fluid material is formed between the lens 150, 250 and the substrate 110, 210 by injection or immersing. Accordingly, the phosphor layer of the light emitting diode package is uniformly and the excited efficiency of the phosphor is enhanced. Furthermore, conductive wires or pads located upon the LED chip may not be dislocated in the manufacturing process, whereby the fabrication yield of the light emitting diode packages is increased.

It is to be understood, however, that even though multiple characteristics and advantages of the disclosure have been set forth in the foregoing description, together with details of the structure and function of the invention disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode package, comprising:
a substrate, comprising two electrodes disconnecting each other and at least two tunnels penetrating the substrate;
a LED chip, disposing on the substrate and electrically connecting to one of the electrodes via at least one conductive wire;
at least one encapsulation, covering a connection between the at least one conductive wire and the one of the electrodes;
a lens, located on the substrate, wherein a collector is located between the substrate and the lens, the LED chip and the at least one encapsulation located inside the collector; and
a phosphor layer, located inside the collector and filled the at least two tunnels.

2. The light emitting diode package as claimed in claim 1, wherein the substrate comprises a first surface and a second surface opposite each other, the LED chip and the two electrodes dispose on the first surface, and the two electrodes respectively extend from the first surface to the second surface.

3. The light emitting diode package as claimed in claim 1, wherein the LED chip has a light emitting angle between 110 to 150°.

4. The light emitting diode package as claimed in claim 1, wherein the encapsulation is transparent.

5. The light emitting diode package as claimed in claim 1, wherein the substrate and the lens are applied each other via an adhesive.

6. A light emitting diode package, comprising:
a substrate, comprising two electrodes disconnecting each other and at least two tunnels penetrating the substrate;
a LED chip, disposing on the substrate and electrically connecting to one of the electrodes via at least one conductive wire;
at least one encapsulation, covering a connection between the at least one conductive wire and the one of the electrodes;
a lens, located on the substrate, wherein a collector is located between the substrate and the lens, and the LED chip and the at least one encapsulation are located inside the collector; and
a transparent layer, formed inside the collector and filled the at least two tunnels;
wherein the transparent layer is injected inside the collector via the at least two tunnels.

7. The light emitting diode package as claimed in claim 6, wherein the substrate comprises a first surface and a second surface opposite each other, the LED chip and the two electrodes dispose on the first surface, and the two electrodes respectively extend from the first surface to the second surface.

8. The light emitting diode package as claimed in claim 6, wherein the LED chip has a light emitting angle between 110 to 150°.

9. The light emitting diode package as claimed in claim 6, wherein the encapsulation is transparent.

10. The light emitting diode package as claimed in claim 6, wherein the transparent layer comprises phosphor particles.

11. The light emitting diode package as claimed in claim 6, wherein the substrate and the lens are applied each other via an adhesive.

12. A method for manufacturing a light emitting diode package, comprising following steps:
providing a substrate, which comprising two electrodes and a LED chip located thereon;
disposing at least one conductive wire electrically connecting the LED chip to one of the electrodes;
forming at least one encapsulation covering a connection between the at least one conductive wire and the one of the electrodes;
forming at least two tunnels penetrating the substrate;
providing a lens disposing on the substrate, wherein the lens covers the at least one encapsulation and the LED chip, and a collector is located between the substrate and the lens;
forming a fluid material inside the collector; and
solidifying the fluid material.

13. The method for manufacturing the light emitting diode package as claimed in claim 12, wherein the fluid material is injected inside the collector and filled the at least two tunnels via the at least two tunnels.

14. The method for manufacturing the light emitting diode package as claimed in claim 12, wherein before the step of providing a lens allocated on the substrate, the fluid material is formed inside the collector of the lens.

15. The method for manufacturing the light emitting diode package as claimed in claim 14, wherein the LED chip and the at least one encapsulation are immersed into the fluid material when providing the lens disposing on the substrate.
